(19) United States
(12) Patent Application Publication
(10) Pub. No.: US 2017/0245367 A1
(43) Pub. Date: Aug. 24, 2017

(54) CIRCUIT CARD ASSEMBLY (CCA) WITH REDUCED SUSCEPTIBILITY TO DEFORM UNDER LOADING

(71) Applicant: Raytheon Company

(72) Inventors: Fazzel Gurrola, Tucson, AZ (US); David W. Homes, Tucson, AZ (US)

(21) Appl. No.: 15/049,454

(22) Filed: Feb. 22, 2016

(51) Int. Cl. H05K 1/18; H05K 1/02

(52) U.S. Cl. CPC H05K 1/18; H05K 1/0203

(57) ABSTRACT

A circuit card assembly (CCA) for reduced susceptibility to load deformation when mounted at peripheral mounting portions is provided. The CCA includes a circuit card including a face to which components are operably connectable, a plate defining openings that correspond to the components, the plate being disposable adjacent to the face with the components extending at least partially through the openings and adhesive interposed between the face and the plate.

### BACKGROUND

The present invention relates to circuit card assemblies (CCAs) and, more specifically, to CCAs with reduced susceptibility to deformation under loading experienced during high-G and/or shock events.

Modern missiles, such as those propelled by rail guns and hypersonic systems, include multiple components. Of these multiple components, circuit card assemblies (CCAs) are responsible for performing electronic functions. However, since modern missile environments subject the multiple components to increasingly high acceleration and shock loads, CCAs are frequently subjected to loads exceeding their unreinforced load capacity. This loading can deform and damage the CCAs and thus protection of CCAs from acceleration or other loading continues to be a major concern in missile design and development.

### SUMMARY

According to one embodiment of the present invention, a circuit card assembly (CCA) for reduced susceptibility to load deformation when mounted at peripheral mounting portions is provided. The CCA includes a circuit card and the circuit card includes a face to which components are operably connectable. The CCA further includes a plate and adhesive. The plate defines openings that correspond to the components with the plate being disposable adjacent to the face and with the components extending at least partially through the openings. The adhesive is interposed between the face and the plate.

According to another embodiment, a system including a circuit card assembly (CCA) having reduced susceptibility to load deformation is provided. The system includes a housing, a circuit card including a first face to which first components are operably connectable and a second face opposite the first face to which second components are operably connectable, mounting elements coupled to the housing and a periphery of the circuit card, first and second plates defining first and second openings that correspond to the first and second components, the first and second plates being disposable adjacent to the first and second faces with the first and second components extending at least partially through the first and second openings and adhesive interposed between the first face and the first plate and between the second face and the second plate.

According to another embodiment, a method is provided to reduce a susceptibility of a circuit card assembly (CCA), which includes a circuit card and components operably connectable to a face of the circuit card, to deform under loading perpendicular to a plane of the circuit card with the CCA being mounted at peripheral mounting portions thereof. The method includes defining openings in a plate that correspond to the components, disposing the plate adjacent to the face with the components extending at least partially through the openings and adhering the plate to the face.

Additional features and advantages are realized through the techniques of the present invention. Other embodiments and aspects of the invention are described in detail herein and are considered a part of the claimed invention. For a better understanding of the invention with the advantages and the features, refer to the description and to the drawings.

### BRIEF DESCRIPTION OF THE SEVERAL VIEWS OF THE DRAWINGS

The subject matter which is regarded as the invention is particularly pointed out and distinctly claimed in the claims at the conclusion of the specification. The foregoing and other features, and advantages of the invention are apparent from the following detailed description taken in conjunction with the accompanying drawings in which:

FIG. 1 is a side view of a missile in accordance with embodiments;

FIG. 2 is an enlarged view of a cross-section of a fuselage of the missile of FIG. 1 taken along line A-A;

FIG. 3 is a perspective view of a circuit card;

FIG. 4 is a side view of the circuit card of FIG. 3 being subjected to loading when mounted;

FIG. 5 is a perspective view of a circuit card assembly (CCA) in accordance with embodiments;

FIG. 6 is a side view of the CCA of FIG. 5 being subjected to loading when mounted;

FIG. 7 is an enlarged side view of the CCA of FIGS. 5 and 6;

FIG. 8 is a plan view of a plate of the CCA that is formed to define openings for CCA components as well as additional openings in accordance with embodiments; and

FIG. 9 is a side view of a CCA in accordance with an alternative embodiment.

### DETAILED DESCRIPTION

As will be described below, an I-beam structure is effectively provided for a circuit card assembly with a circuit card assembly at its core. The I-beam structure is achieved by the application of a layer of epoxy or other adhesive to each side of the circuit card assembly and then sandwiching the circuit card assembly between two high strength metal/composite plates. The plates provide structural support for the circuit card assembly under high loading and also act as a thermal heat sink, an electro-magnetic interference (EMI) barrier, an anti-tamper feature and an environmental isolation element.

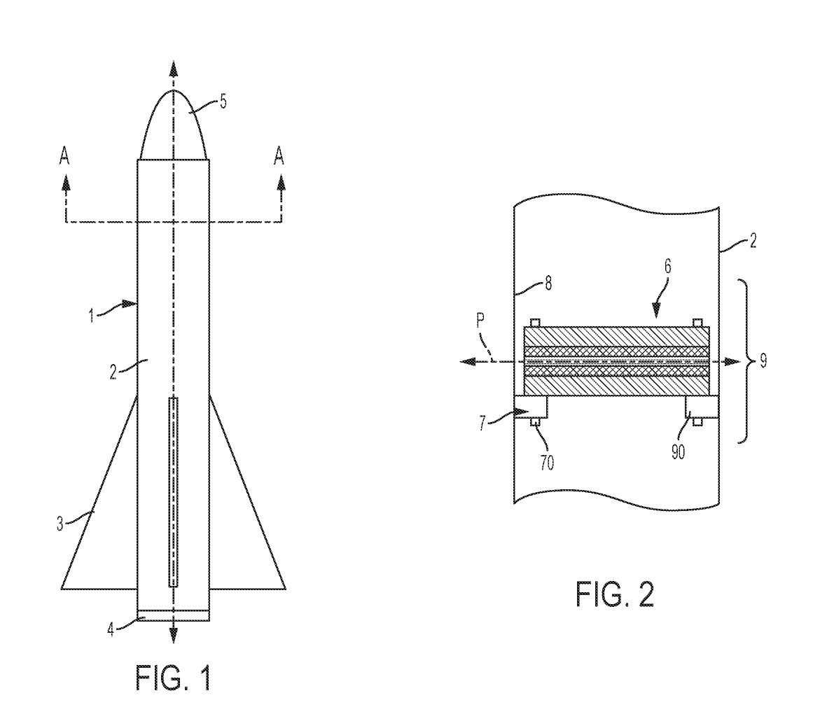

With reference to FIGS. 1 and 2, an aircraft in which the I-beam structure may be installed is provided for reference. The aircraft may be configured as a missile 1 or another similar type of manned or unmanned, guided or unguided vehicle. The missile 1 includes an elongated fuselage 2, fins 3 with controllable aerodynamic surfaces, at least one engine 4 at an aft end of the fuselage 2 (the engine 4 may be discarded in the case of a ballistic missile or a gravity bomb), a nose cone section 5 situated at the forward end of the fuselage 2, a circuit card assembly (CCA) 6 and mounting elements 7. The fuselage 2 may be provided as a substantially tubular body 8 having a mounting section 9 defined therein.

Within the mounting section 9, the tubular body 8 may include a mounting flange 90 to which the CCA 6 is mountable by the mounting elements 7. The mounting elements 7 may be provided as mounting pins 70 that are respectively and indirectly coupled to the fuselage 2 via the mounting flange 90 or to the fuselage 2 directly. In the latter case, the mounting pins 70 may be secured to both the mounting flange 90 and a periphery of the CCA 6. In accordance with embodiments, where the tubular body 8 is cylindrical, the mounting flange 90 may be annular or ring-shaped and tightly fittable to an interior facing surface of the tubular body 8. The CCA 6 is configured to exhibit a reduced susceptibility to deform under various types of loading to which it is exposed.

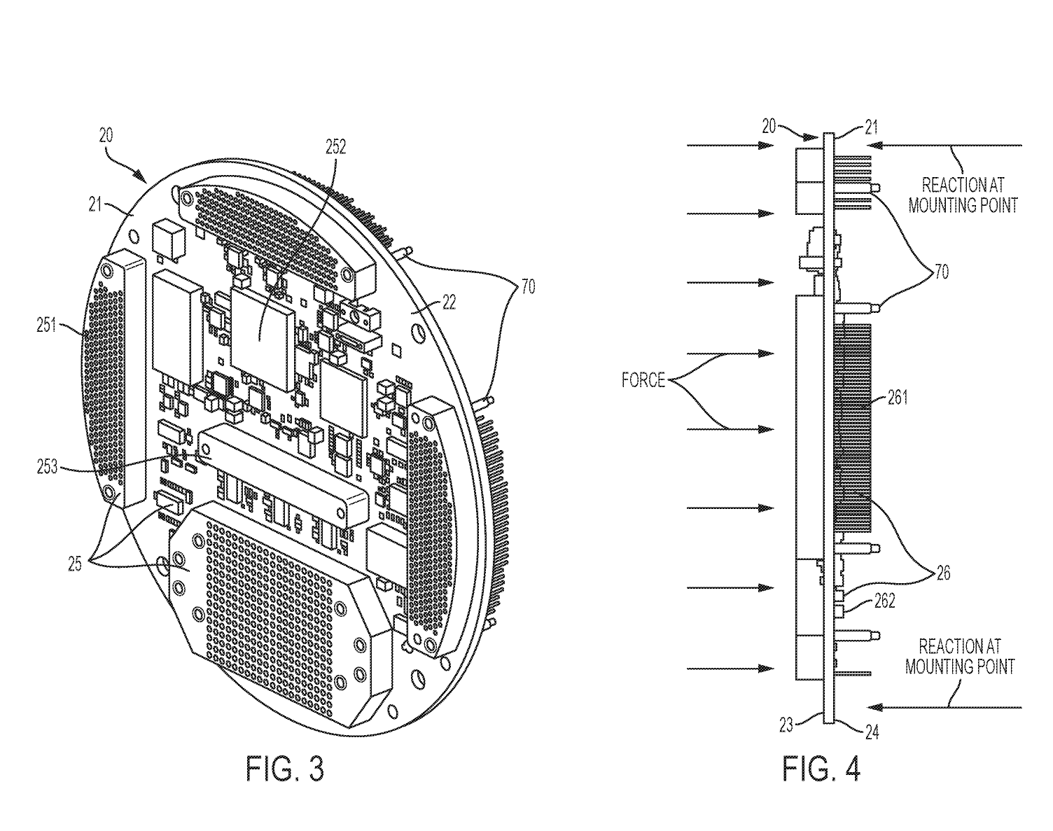

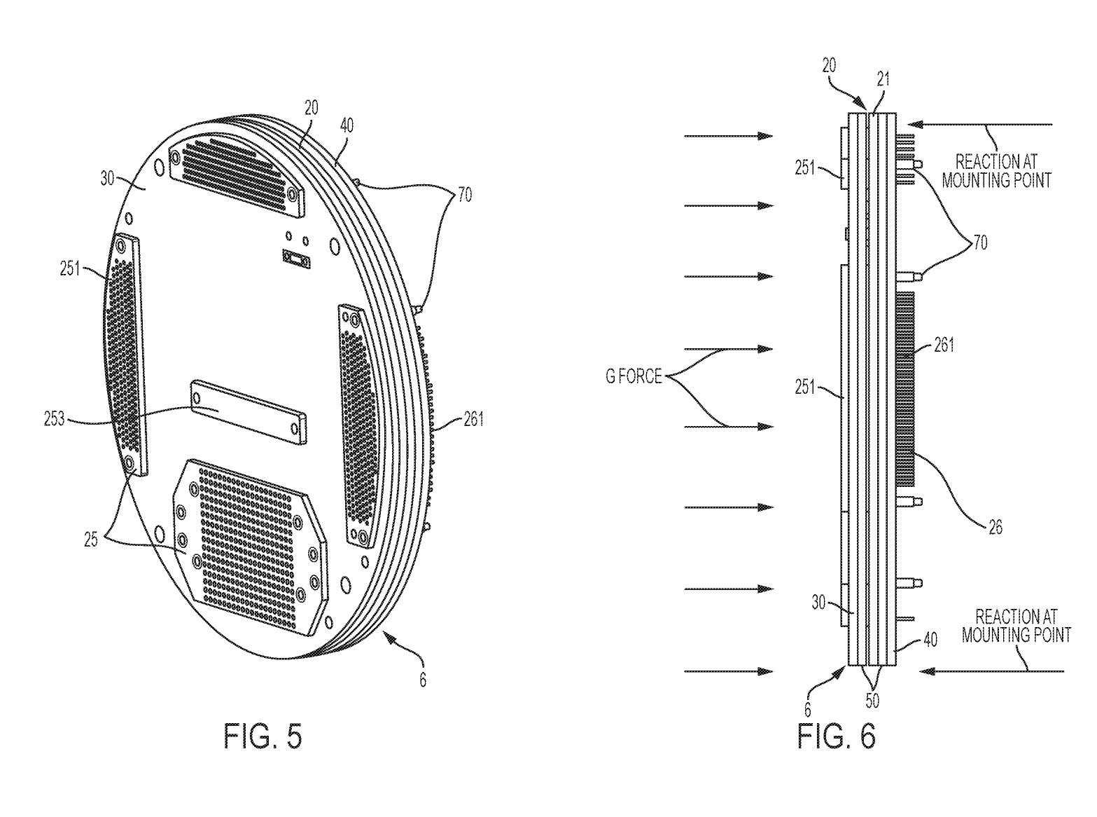

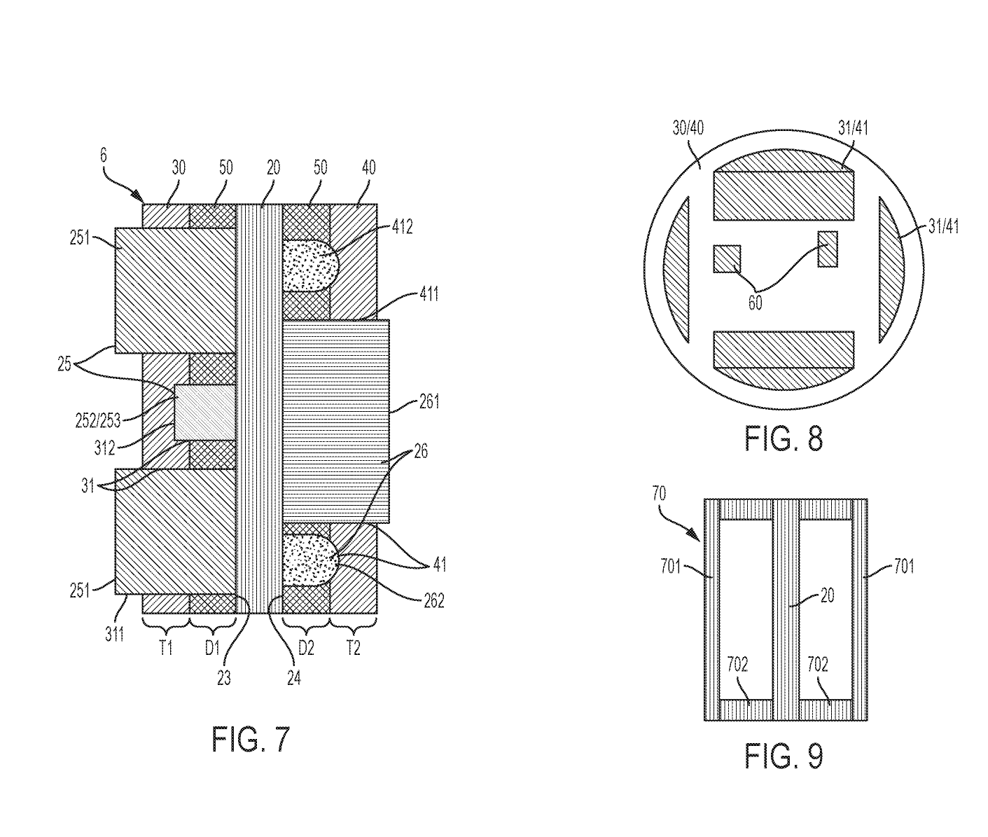

With reference to FIGS. 3 and 4 and to FIGS. 5-7, the CCA 6 (see FIGS. 6 and 7) includes a circuit card 20, a first plate 30, a second plate 40 and adhesive 50 (the first plate 30, the second plate 40 and the adhesive are only shown in FIGS. 6 and 7). The circuit card 20 may be provided as a printed circuit board (PWB) 21 and includes a body 22 (see FIG. 3), which may be annular in accordance with some embodiments, a first face 23 at a first side of the body 22 and a second face 24 opposite the first face 23 at a second side of the body 22. The circuit card 20 further includes first CCA components 25 and second CCA components 26. The first CCA components 25 are operably connectable to the first face 23 by at least one or more of solder, adhesive, mechanical fastening and mechanical interference and may include card connectors 251 of varying size and shape, chip packages 252 of varying size and shape and heat sinks 253 of varying size and shape. The second CCA components 26 are operably connectable to the second face 24 by at least one or more of solder, adhesive, mechanical fastening and mechanical interference and may include pin arrays 261 of varying size and shape and solder bumps 262.

In accordance with embodiments, the first plate 30 and the second plate 40 may be formed of high strength metallic or composite materials. The adhesive 50 may be interposed between the first plate 30 and the first face 23 and between the second plate 40 and the second face 24 and may include epoxy, thermoplastics or other similar adhesive materials. The respective combinations of the first plate 30 and the adhesive 50 as well as the second plate 40 and the adhesive 50 provide for I-beam type structural support of the circuit card 20 under cross-plane loading, which is defined as being directed perpendicularly with respect to a plane P (see FIG. 2) of the circuit card 20, thermal heat sinks, electro-magnetic interference (EMI) barriers, anti-tamper features and environmental isolation elements.

Although the description provided herein and the drawings illustrate embodiments in which both the first plate 30 and the second plate 40 are present, it is to be understood that this is done for purposes of clarity and brevity and that this configuration is not necessary. Indeed, embodiments exist in which only one of the first plate 30 and the second plate 40 are provided. In addition, where the body 22 of the circuit card 20 is annular, the first plate 30 and the second plate 40 may be similarly annular although this is not required and it is to be understood that both the first and second plates 30 and 40 may have unique shapes and sizes relative to each other and to the circuit card 20.

In accordance with embodiments, the first CCA components 25 and the second CCA components 26 cooperatively perform electronic functions and operations on board the missile 1. Such electronic functions and operations may include, but are not limited to, navigational and flight controls, power supply, sensor operations, payload monitoring and ground-to-air, air-to-air and satellite communications.

In any case, as shown in FIG. 7, the first plate 30 has a first thickness T1 and is formed to define first openings 31 that respectively correspond in terms of shapes, sizes and locations to the first CCA components 25 such that the first plate 30 covers as much of the first face 23 as possible. The first plate 30 is disposable adjacent to the first face 23 at a first distance D1 with the first CCA components 25 extending at least partially into and through the first openings 31. That is, for those first CCA components 25 whose height as measured from the first face 23 is equal to or greater than a combined length of the first thickness T1 and the first distance D1 (e.g., the card connectors 251), the first openings 31 may be provided as first apertures 311 extending from a first side of the first plate 30, which faces away from the first face 23, to a second side of the first plate 30, which faces toward the first face 23.

Meanwhile, for those first CCA components 25 whose height as measured from the first face 23 is greater than the first distance D1 but less than the combined length of the first thickness T1 and the first distance D1 (e.g., some of the chip packages 252 and the heat sinks 253), the first openings 31 may be provided as first recesses 312 extending into the first plate 30 from the second side of the first plate 30.

The second plate 40 has a second thickness T2 and is formed to define second openings 41 that respectively correspond in terms of shapes, sizes and locations to the second CCA components 26. The second plate 40 is disposable adjacent to the second face 24 at a second distance D2 with the second CCA components 26 extending at least partially into and through the second openings 41. That is, for those second CCA components 26 whose height as measured from the second face 24 is equal to or greater than a combined length of the second thickness T2 and the second distance D2 (e.g., the pin arrays 261), the second openings 41 may be provided as second apertures 411 extending from a first side of the second plate 30, which faces toward from the second face 24, to a second side of the first plate 30, which faces away from the second face 24.

Meanwhile, for those second CCA components 26 whose height as measured from the second face 24 is greater than the second distance D2 but less than the combined length of the second thickness T2 and the second distance D2 (e.g., the solder bumps 262), the second openings 41 may be provided as second recesses 412 extending into the second plate 40 from the first side of the second plate 40.

In conventional systems, as shown in FIGS. 3 and 4, CCAs do not include either of the first plate 30 or the second plate 40. Thus, CCAs in conventional systems lack I-beam type structural circuit card support under cross-plane gravitational loading, thermal heat sinks, electro-magnetic interference (EMI) barriers, anti-tamper features and environmental isolation elements. As to the lack of the I-beam type structural support, when CCAs in conventional systems are mounted at the CCA periphery, cross-plane gravitational loading (defined as gravitational loading applied to the CCA substantially uniformly or non-uniformly along its face perpendicularly with respect to a plane of the circuit card and which is opposed by mounting point reactions) tends to cause CCA deformation. Such CCA deformation may manifest as a bowing of the CCA and may lead to CCA components popping off of the circuit card where the bowing effect overcomes the strength of the connections between the CCA components and the circuit card.

By contrast, as shown in FIGS. 5 and 6, the CCA 6 includes at least one or both of the first plate 30 and the second plate 40 and thus obtains a benefit of I-beam type structural support under cross-plane gravitational or other types of loading, thermal heat sinks, electro-magnetic interference (EMI) barriers, anti-tamper features and environmental isolation elements. As to the presence of I-beam type structural support, when the CCA 6 is mounted to the mounting flange 90/fuselage 2 by the mounting pins 70 at the periphery of the CCA 6, deformation of the circuit card 20 caused by cross-plane gravitational loading (defined again as gravitational loading applied to the CCA 6 substantially uniformly or non-uniformly along the first face 23 perpendicularly with respect to the plane P of the circuit card 20 and which is opposed by mounting point reactions at the coupling location of the mounting pins 70 and the CCA 6) or any other types of loading is prevented or substantially reduced by the first plate 30 and the second plate 40. Therefore, bowing of the circuit card 20 and the resultant disconnections of the first and second CCA components 25 and 26 are avoided.

In accordance with further embodiments and, with reference to FIG. 8, at least one or both of the first plate 30 and the second plate 40 may be formed to define the first openings 31/second openings 41 as well as a limited number of additional openings 60. As shown in FIG. 8, these additional openings 60 may be provided as apertures or recesses that are similar to those described above but are not associated with or corresponding to the first or second CCA components 25 or 26. Rather, the additional openings 60 are provided to reduce an overall weight of the CCA 6 without unduly sacrificing I-beam type structural support strength, thermal heat sink capabilities, electro-magnetic interference (EMI) barrier capabilities, anti-tampering capabilities and environmental isolation capabilities.

In accordance with further embodiments and, with reference to FIG. 9, at least one or both of the first plate 30 and the second plate 40 may be replaced with member 70. As shown in FIG. 9, member 70 is integrally formed with the circuit card 20 and includes base member 701 and pin support members 702, which extend between the base member 701 and the circuit card 20.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one more other features, integers, steps, operations, element components, and/or groups thereof.

The corresponding structures, materials, acts and equivalents of all means or step plus function elements in the claims below are intended to include any structure, material or act for performing the function in combination with other claimed elements as claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

While embodiments have been described, it will be understood that those skilled in the art, both now and in the future, may make various improvements and enhancements which fall within the scope of the claims which follow. These claims should be construed to maintain the proper protection for the invention first described.

What is claimed is:

1. A circuit card assembly (CCA) for reduced susceptibility to load induced deformation when mounted at peripheral mounting portions, the CCA comprising:
a circuit card including a face to which components are operably connectable;
a plate defining openings that correspond to the components, the plate being disposable adjacent to the face with the components extending at least partially through the openings; and
adhesive interposed between the face and the plate.

2. The CCA according to claim 1, further comprising mounting elements configured for coupling with a periphery of the circuit card.

3. The CCA according to claim 1, wherein the components are operably connectable to the face by at least one or more of solder, adhesive, mechanical fastening and mechanical interference.

4. The CCA according to claim 1, wherein the components comprise card connectors, chip packages, heat sinks, pin arrays and solder bumps.

5. The CCA according to claim 1, wherein the openings comprise recesses and apertures.

6. The CCA according to claim 1, wherein the plate defines additional openings.

7. The CCA according to claim 1, wherein the plate comprises at least one of high strength metallic or composite material.

8. The CCA according to claim 1, wherein the adhesive comprises at least one of epoxy or thermoplastic.

9. A system including a circuit card assembly (CCA) having reduced susceptibility to load deformation, the system comprising:
a fuselage;
a circuit card including a first face to which first components are operably connectable and a second face opposite the first face to which second components are operably connectable;
mounting elements coupled to the fuselage and a periphery of the circuit card;
first and second plates defining first and second openings that correspond to the first and second components, the first and second plates being disposable adjacent to the first and second faces with the first and second components extending at least partially through the first and second openings; and
adhesive interposed between the first face and the first plate and between the second face and the second plate.

10. The system according to claim 9, wherein the fuselage comprises a tubular body.

11. The system according to claim 9, wherein the mounting elements comprise mounting pins.

12. The system according to claim 9, wherein the first and second components are operably connectable to the first and second faces by at least one or more of solder, adhesive, mechanical fastening and mechanical interference.

13. The system according to claim 9, wherein the first components comprise card connectors, chip packages and heat sinks and the second components comprise pin arrays and solder bumps.

14. The system according to claim 9, wherein the first and second openings comprise recesses and apertures.

15. The system according to claim 9, wherein the first and second plates are formed to define additional openings.

16. The system according to claim 9, wherein the first and second plates comprise at least one of high strength metallic material and ceramic.

17. The system according to claim 9, wherein the adhesive comprises at least one of epoxy and thermoplastic.

18. A method of reducing a susceptibility of a circuit card assembly (CCA), which includes a circuit card and components operably connectable to a face of the circuit card, to deform under loading perpendicular to a plane of the circuit card with the CCA being mounted at peripheral mounting portions thereof, the method comprising:
defining openings in a plate that correspond to the components;
disposing the plate adjacent to the face with the components extending at least partially through the openings; and
adhering the plate to the face.

19. The method according to claim 18, wherein defining of the openings comprises defining the openings to respectively correspond to sizes, shapes and locations of the openings.

20. The method according to claim 18, further comprising defining additional openings in the plate.
